(19) United States
(12) Patent Application Publication
(10) Pub. No.: US 2026/0190599 A1
(43) Pub. Date: Jul. 2, 2026

(54) X-RAY IMAGE SENSOR, SENSING FILM AND METHOD FOR MANUFACTURING THE SAME

(71) Applicant: Industrial Technology Research Institute, Hsinchu (TW)

(72) Inventors: Kai-Xiang Hsu, Taichung City (TW); Kuo-Wei Huang, Yunlin County (TW); Jen-An Chen, Miaoli County (TW); Ming-Tsun Kuo, Hsinchu County (TW)

(73) Assignee: Industrial Technology Research Institute, Hsinchu (TW)

(21) Appl. No.: 19/190,809

(22) Filed: Apr. 28, 2025

(30) Foreign Application Priority Data
Dec. 31, 2024 (TW) 113151632

(51) Int. Cl. H10K 39/36; G01T 1/202; H10K 71/00; H10K 71/12; H10K 85/50

(52) U.S. Cl. CPC H10K 39/36; G01T 1/2023; H10K 71/12; H10K 71/311; H10K 85/50

(57) ABSTRACT

A sensing film of an X-ray image sensor includes a multilayer colloidal halide perovskite nanocrystal, wherein different layers of the colloidal halide perovskite nanocrystal have different crystal sizes. A method for manufacturing a sensing film of an X-ray image sensor includes preparing several colloidal solutions and then spraying the colloidal solutions to form a multilayer colloidal halide perovskite nanocrystal. Each of the colloidal solutions includes halide perovskite nanocrystals of different crystal sizes.

### CROSS-REFERENCE TO RELATED APPLICATION

This application claims the priority benefit of Taiwan application serial no. 113151632, filed on Dec. 31, 2024. The entirety of the above-mentioned patent application is hereby incorporated by reference herein and made a part of this specification.

### BACKGROUND

### Technical Field

This disclosure relates to an X-ray image sensor, a sensing film, and a method for manufacturing the same.

### Related Art

Due to the high sensitivity advantage of perovskite materials when applied to X-ray sensing films, there have been studies on various perovskite sensing films, such as halide perovskite nanocrystal sensing films.

However, the emission wavelength ranges of the aforementioned perovskite nanocrystals largely overlap, resulting in a small Stokes shift, which causes self-absorption phenomena, thereby reducing fluorescence emission performance. For sensing high-energy radiation, a scintillation layer of hundreds of micrometers or more in thickness is required. As the thickness further increases, the impact of self-absorption significantly intensifies, and the radioluminescence (RL) intensity may severely decrease. Therefore, providing an X-ray sensing film that can reduce self-absorption while maintaining good RL intensity may be an urgent need in the industry.

### SUMMARY

A sensing film of an X-ray image sensor disclosed herein includes a multilayer colloidal halide perovskite nanocrystal, wherein the colloidal halide perovskite nanocrystals in different layers have different crystal sizes.

The X-ray image sensor of the disclosure includes the sensing film.

A method for manufacturing a sensing film of an X-ray image sensor disclosed herein includes the followings. Multiple colloidal solutions are formulated. Then the colloidal solutions are sprayed to form a multilayer colloidal halide perovskite nanocrystal. Each of the colloidal solutions includes halide perovskite nanocrystals with different crystal sizes.

Based on the above, the disclosure utilizes the multilayer colloidal halide perovskite nanocrystal, with colloidal halide perovskite nanocrystals in different layers having different crystal sizes, to achieve red shift in fluorescence emission wavelength while enhancing the sensed radioluminescence (RL) intensity, thereby improving the response rate with a photodiode.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1A is a schematic diagram of an X-ray image sensor according to a first embodiment of the disclosure.

FIG. 1B is a schematic diagram of a sensing film of the X-ray image sensor in FIG. 1A.

FIG. 2 is a diagram illustrating manufacturing steps of a sensing film for an X-ray image sensor according to a second embodiment of the disclosure.

FIG. 3 is a diagram illustrating steps for formulating a colloidal solution in FIG. 2.

FIG. 4 is an X-ray diffraction (XRD) diagram of Experimental Example 2.

FIG. 5 is an XRD diagram of Experimental Example 3 and Experimental Example 4.

FIG. 6 is a schematic diagram of ultrasound spraying in Experimental Example 5.

### DETAILED DESCRIPTION OF DISCLOSURED EMBODIMENTS

The following embodiments are described in detail with reference to the accompanying drawings, but the provided embodiments are not intended to limit the scope covered by this disclosure. Furthermore, the drawings are for illustrative purposes only and are not drawn to scale. For ease of understanding, the same elements in the following description will be explained using the same reference numerals.

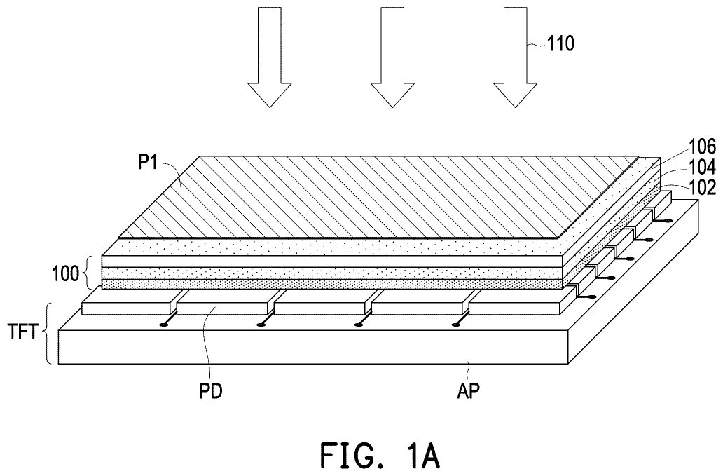

FIG. 1A is a schematic diagram of an X-ray image sensor according to a first embodiment of the disclosure. In FIG. 1A, the X-ray image sensor basically includes a sensing film 100 shown in FIG. 1B.

Please continue to refer to FIG. 1A. In addition to the sensing film 100, the X-ray image sensor may also include a protective layer P1 and an amorphous silicon thin-film transistor TFT. The protective layer P1 is located above the sensing film 100 to isolate the sensing film 100 from external environmental influences, where the protective layer P1 is, for example, aluminum foil. The amorphous silicon thin-film transistor TFT is located below the sensing film 100. The amorphous silicon thin-film transistor TFT includes an array substrate AP and multiple amorphous silicon photodiodes PD on the array substrate AP.

When an X-ray 110 is irradiated from above the sensing film 100 and passes through the object to be measured (not shown), it passes through the sensing film 100 to reach the amorphous silicon thin-film transistor TFT. The amorphous silicon photodiode PD on each pixel of the amorphous silicon thin-film transistor TFT may convert the fluorescence emitted by the sensing film 100 into electrical signals, where the stronger the fluorescence signal, the greater the photocurrent generated. After the electrical signal passes through an analog-to-digital converter (ADC), it can be reconstructed into a complete image through signal processing. In addition to the schematic components shown in FIG. 1A, the X-ray image sensor may also adopt known X-ray image sensor systems, therefore the details of the X-ray image sensor are not described in the following.

Please refer to FIG. 1B. The sensing film 100 of the X-ray image sensor includes a multilayer colloidal halide perovskite nanocrystal, such as a first layer 102, a second layer 104, and a third layer 106 shown in the figure; however, this disclosure is not limited thereto. In some embodiments, the number of layers of colloidal halide perovskite nanocrystal may be a bilayer, that is, only including the first layer 102 and the second layer 104; or only including the second layer 104 and the third layer 106, and so on. In this disclosure, the colloidal halide perovskite nanocrystal in different layers have different crystal sizes. In some embodiments, the crystal sizes of the multilayer colloidal halide perovskite nanocrystal are, for example, between 1 nm and 100 nm. For instance, for X-ray response, the crystal size of the colloidal halide perovskite nanocrystal in the first layer 102 is larger than the crystal size of the colloidal halide perovskite nanocrystal in the second layer 104, and the crystal size of the colloidal halide perovskite nanocrystal in the second layer 104 is larger than the crystal size of the colloidal halide perovskite nanocrystal in the third layer 106, which may increase the radioluminescence intensity (RL intensity). Therefore, the crystal sizes of the multilayer colloidal halide perovskite nanocrystal are stacked from large to small crystal sizes sequentially from the bottom layer to the top layer. In some embodiments, the crystal size of the colloidal halide perovskite nanocrystal in the first layer 102 is, for example, between 9 nm and 20 nm. In some embodiments, the crystal size of the colloidal halide perovskite nanocrystal in the second layer 104 is, for example, between 3 nm and 9 nm. In some embodiments, the crystal size of the colloidal halide perovskite nanocrystal in the third layer 106 is, for example, between 1 nm and 3 nm. However, this disclosure is not limited thereto. In some embodiments, the crystal sizes of the three-layer structure consisting of the first layer 102, the second layer 104, and the third layer 106 are composed of medium, small, and large sizes, for instance, the crystal size of the colloidal halide perovskite nanocrystal in the first layer 102 is between 3 nm and 9 nm, the crystal size of the colloidal halide perovskite nanocrystal in the second layer 104 is between 1 nm and 3 nm, and the crystal size of the colloidal halide perovskite nanocrystal in the third layer 106 is between 9 nm and 20 nm. In some embodiments, the crystal sizes of the three-layer structure consisting of the first layer 102, the second layer 104, and the third layer 106 are composed of medium, large, and small sizes, for instance, the crystal size of the colloidal halide perovskite nanocrystal in the first layer 102 is between 3 nm and 9 nm, the crystal size of the colloidal halide perovskite nanocrystal in the second layer 104 is between 9 nm and 20 nm, and the crystal size of the colloidal halide perovskite nanocrystal in the third layer 106 is between 1 nm and 3 nm.

In some implementations, if the number of layers of colloidal halide perovskite nanocrystal is a bilayer and only includes the first layer 102 and the second layer 104, the crystal size of the colloidal halide perovskite nanocrystal in the first layer 102 may be larger than the crystal size of the colloidal halide perovskite nanocrystal in the second layer 104. Therefore, the crystal sizes of the multilayer colloidal halide perovskite nanocrystal are stacked from large to small crystal sizes sequentially from the bottom layer to the top layer. In some embodiments, if the number of layers of colloidal halide perovskite nanocrystal is a bilayer and only includes the second layer 104 and the third layer 106, for X-ray response, the crystal size of the colloidal halide perovskite nanocrystal in the second layer 104 may be smaller than the crystal size of the colloidal halide perovskite nanocrystal in the third layer 106, which may have a higher RL intensity; for ultraviolet light (365 nm) response, the crystal size of the colloidal halide perovskite nanocrystal in the second layer 104 may be smaller than the crystal size of the colloidal halide perovskite nanocrystal in the third layer 106, which may have a higher photoluminescence intensity (PL intensity), for instance, the crystal size of the colloidal halide perovskite nanocrystal in the second layer 104 is between 3 nm and 9 nm, and the crystal size of the colloidal halide perovskite nanocrystal in the third layer 106 is between 9 nm and 20 nm. In some embodiments, if the number of layers of colloidal halide perovskite nanocrystal is a bilayer and only includes the second layer 104 and the third layer 106, it has been verified that when the crystal size of the colloidal halide perovskite nanocrystal in the second layer 104 is larger than the crystal size of the colloidal halide perovskite nanocrystal in the third layer 106, it also has a high radioluminescence intensity, for instance, the crystal size of the colloidal halide perovskite nanocrystal in the second layer 104 is between 9 nm and 20 nm, and the crystal size of the colloidal halide perovskite nanocrystal in the third layer 106 is between 3 nm and 9 nm.

A chemical formula of the colloidal halide perovskite nanocrystal disclosed in this disclosure is ABX₃, and organic ligands may be introduced, where A includes monovalent metal cations or monovalent organic amine cations, B includes divalent metal cations, X includes halogen anions, and the organic ligands include carboxyl groups (RCOOH), alkylamines (RNH₂) or combinations thereof. In some embodiments, A is selected from at least one of Cs⁺, Rb⁺, CH₃NH₃⁺ and CH(NH₂)₂⁺; B is selected from at least one of Pb²⁺ and Sn²⁺; X is selected from at least one of Cl⁻, Br⁻ and I⁻. In some embodiments, the organic ligands are selected from at least one of combinations of octanoic acid and octylamine, or oleic acid and oleylamine.

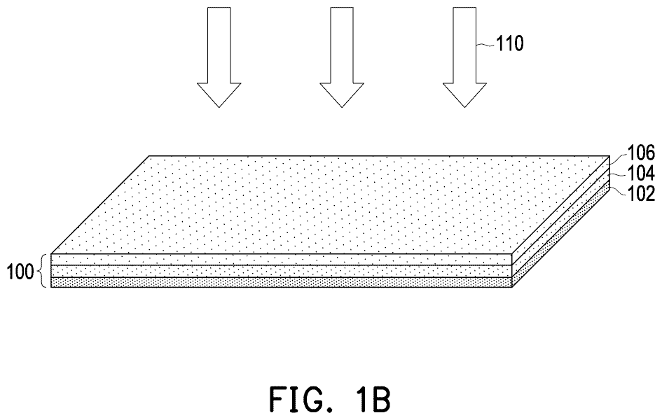

FIG. 2 is a diagram illustrating manufacturing steps of a sensing film for an X-ray image sensor according to a second embodiment of the disclosure. In FIG. 2, a manufacturing method 200 includes formulating multiple colloidal solutions (step 202) and spraying (step 204).

In step 202, each colloidal solution includes halide perovskite nanocrystals with different crystal sizes, and the material selection for the colloidal halide perovskite nanocrystals may refer to the previous embodiment, which is not repeated in the following. In some embodiments, the concentration of the colloidal solution may be 10 mg/mL to 150 mg/mL.

In step 204, each colloidal solution may be sprayed separately. The method for spraying the colloidal solution includes inkjet method or ultrasound spray process. In some embodiments, compared to the inkjet method, adopting the ultrasound spray process may mitigate the phenomenon of reducing radiant light intensity, while causing a red shift in emission wavelength, improving the response rate of the photodiode. The method of the ultrasound spray process, for example, atomizes one of multiple colloidal solutions into droplets at an ultrasound frequency of 20 Hz to 100 Hz, and assists the droplets to deposit on a substrate with dry air, argon gas, or nitrogen gas; subsequently, the atomization and deposition steps are repeated for another colloidal solution among the multiple colloidal solutions, forming another layer of colloidal halide perovskite nanocrystals on the previous layer. Multilayer colloidal halide perovskite nanocrystal may be formed through repeated spraying. According to the ultrasound spray process, the upper and lower layers in the multilayer colloidal halide perovskite nanocrystal of this embodiment may directly contact each other without interface formation, thus preventing further scattering during photon migration, which leads to reduced radiated light intensity phenomenon. Moreover, the aforementioned process is simple, low-cost, and may be extended to color X-ray image applications.

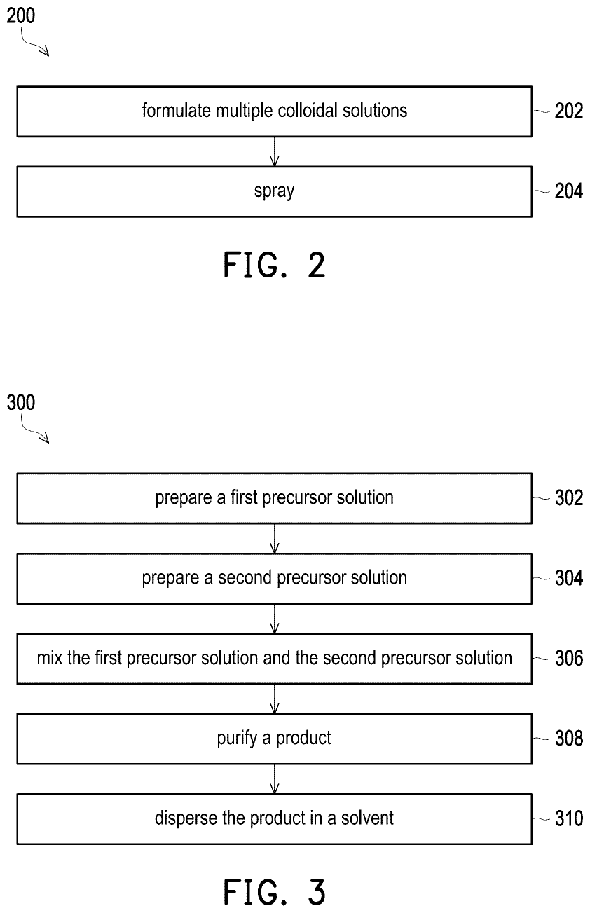

FIG. 3 is a diagram illustrating steps for formulating a colloidal solution 200 in FIG. 2.

In a formulation method 300 of multiple colloidal solutions in FIG. 3, step 302 may be conducted first to prepare a first precursor solution, wherein the first precursor solution includes a first precursor, an alcoholic polar solvent, and a non-polar solvent. In some embodiments, the first precursor may be a cesium precursor (e.g., cesium acetate precursor solution), formamidine acetate (FAAc) precursor solution, or methylamine acetate (MAAc) precursor solution. From the perspective of good product stability, the first precursor may be a cesium precursor or methylamine acetate precursor solution. In some embodiments, the alcoholic polar solvent may include n-propanol, isopropanol, n-butanol, tert-butanol, or n-hexanol. Moreover, strongly polar solvents such as methanol and ethanol cannot synthesize the multilayer colloidal halide perovskite nanocrystal of this embodiment. In some embodiments, the non-polar solvent may include n-hexane, toluene, octane or heptane. In the method disclosed herein, the crystal size and morphology of the formed halide perovskite nanocrystals may be controlled by regulating the polarity of the reaction solvent, achieving tunable emission spectra. In some embodiments, the alcoholic polar solvent and non-polar solvent are n-propanol and n-hexane respectively, and the volume ratio of n-propanol to n-hexane may be 5:1 to 1:8. In other embodiments, the smaller the volume ratio of n-propanol to n-hexane, the smaller the crystal size; the larger the volume ratio of n-propanol to n-hexane, the larger the crystal size. The smaller the volume ratio of n-propanol to n-hexane, the smaller the emission wavelength (blue shift in emission wavelength); the larger the volume ratio of n-propanol to n-hexane, the larger the emission wavelength (red shift in emission wavelength).

In step 304, a second precursor solution is prepared, wherein the second precursor solution includes a second precursor and an organic ligand. Additionally, the second precursor solution also contains a solvent. In some embodiments, the second precursor may be a lead precursor, such as lead bromide (PbBr₂). In some embodiments, the order of step 302 and step 304 may be interchanged.

In step 306, the first precursor solution and the second precursor solution are mixed to obtain a product. In some embodiments, the reaction temperature of the first precursor solution and the second precursor solution may be from 80° C. to 120° C. In some embodiments, the reaction time of the first precursor solution and the second precursor solution may be from 30 seconds to 10 minutes. In an embodiment of this disclosure, the composition of the formed halide perovskite nanocrystals may be controlled through the mole ratio between the first precursor and the second precursor. When the first precursor and the second precursor are cesium precursor and lead precursor respectively, the mole ratio of cesium precursor to lead precursor may be from 1:1 to 1:6. Experimental results have confirmed that when the mole ratio of cesium precursor to lead precursor is from 1:1 to 1:1.4, the obtained product is Cs₄PbBr₆ nanocrystals; when the mole ratio of cesium precursor to lead precursor is less than 1:1.4 and greater than 1:3, the obtained product is CsPbBr₃/Cs₄PbBr₆ mixed structure nanocrystals; when the mole ratio of cesium precursor to lead precursor is from 1:3 to 1:6, the obtained product is CsPbBr₃. From the perspective of enhancing radiation efficiency, selecting CsPbBr₃/Cs₄PbBr₆ mixed structure nanocrystals is beneficial for improving radiation efficiency.

In step 308, the product is purified. In some embodiments, the method of purification may include first removing the supernatant from the solution obtained in step 306 by centrifugation, and dispersing the bottom precipitate in toluene, then centrifuging again, and removing the supernatant once more.

In step 310, the product obtained from step 308 is dispersed in a solvent to obtain multiple colloidal solutions. In some embodiments, the solvent may be toluene or n-hexane.

The following experiments are listed to verify the implementation effects of this disclosure, but this disclosure is not limited to the following content.

### Raw Materials

1. First precursor: cesium acetate (Thermo Fisher Scientific, 99.9%) precursor solution, FAAc (Thermo Fisher Scientific, 99%) precursor solution, MAAc (Greatcell Solar Materials, 99%) precursor solution.
2. n-propanol (n-PrOH) (DUKSAN PURE CHEMICALS CO., LTD, >99%).
3. n-hexane (DUKSAN PURE CHEMICALS CO., LTD, 95%).
4. Second precursor: lead bromide (Thermo Fisher Scientific, 98+%).
5. Organic ligands: octanoic acid (Thermo Fisher Scientific, 99%), octylamine (Thermo Fisher Scientific, 99%).
6. Toluene (Macron, 99%).

### Experimental Example 1

First, 0.3071 g of cesium acetate and 28.8 mL of mixed solvent of n-propanol and n-hexane were weighed and added to a glass bottle. The mixture was stirred at room temperature under atmospheric conditions to complete the preparation of the cesium precursor solution. Moreover, different cesium precursor solutions were obtained by adopting different volume ratios of n-propanol to n-hexane, wherein the volume ratios are shownin the following Table 1.

Then, 1.77 g to 3.52 g of lead bromide and 4.32 mL of n-propanol were weighed and added to a single-neck flask. The single-neck flask was heated and stirred. Afterwards, 4.32 mL of octanoic acid and 4.32 mL of octylamine were added sequentially. The temperature of the single-neck flask was raised to 80° C.-120° C. After the solution became clear, the preparation of the lead precursor solution was completed.

The lead precursor solution was rapidly injected into the cesium precursor solution to completely mix the cesium precursor solution and the lead precursor solution, and the reaction was conducted for 1 to 3 minutes, whereupon the solution immediately turned yellow-green. The reaction temperature was 100° C. If the reaction time is less than 1 minute, the reaction may not be complete; if the reaction time exceeds 3 minutes, the crystals may continue to grow, resulting in greater differences in crystal size.

The yellow-green solution was centrifuged to remove the supernatant, and the precipitate at the bottom was dispersed in toluene. Centrifugation was performed again, and the supernatant was removed to obtain the purified product.

The purified product was dispersed in toluene solvent to complete the preparation of the colloidal CsPbBr₃ nanocrystal solution.

The colloidal solution was atomized into droplets using an ultrasonic nozzle and deposited on a transparent glass substrate. A spectrometer was adopted to analyze the emission spectrum (PL), full width at half maximum (FWHM), and photoluminescence quantum yield (PLQY, %). The nanocrystal size was analyzed by dropping the colloidal solution onto a copper mesh and examining it with a transmission electron microscope (TEM).

Then, the emission spectra (PL) of the colloidal CsPbBr₃ nanocrystals formed with different reaction solvent polarities were measured, and the PL wavelength (emission center wavelength), full width at half maximum (FWHM), and photoluminescence quantum yield (PLQY) were obtained from the PL spectra. The results are shown in the following Table 1.

Moreover, the TEM images of each colloidal CsPbBr₃ nanocrystal may be obtained using a scanning electron microscope to determine their crystal size, and the results are shown in the following Table 1. In addition, it was discovered from the TEM images that as the volume ratio of n-propanol to n-hexane gradually increased from 1:5 to 3:1, when the polarity increased, the crystal size increased, and the crystal morphology transformed from a flaky structure to a cubic structure. The flaky crystals assembled with adjacent nanoplates in a face-to-face manner with a larger surface, while the cubic crystals displayed a relatively scattered structural arrangement.

TABLE 1

| | volume ratio of n-propanol to n-hexane | | | | | | |
|---|---|---|---|---|---|---|---|
| | 1:5 | 1:4 | 1:3 | 1:2 | 1:1 | 2:1 | 3:1 |
| PL wavelength (nm) | 513 | 517 | 522 | 525 | 527 | 532 | 533 |
| FWHM (nm) | 24.13 | 23.36 | 22.94 | 25.11 | 24.87 | 28.12 | 28.26 |
| PLQY (%) | 42.38 | 45.50 | 42.04 | 42.63 | 41.77 | 34.74 | 33.05 |
| crystal size (nm) | ≈1.5 | ≈1.8 | ≈2.1 | ≈3.1 | ≈6.9 | ≈9.8 | ≈10.9 |

From Table 1, it may be obtained that changing the polarity of the reaction solvent can control the crystal size of the formed halide perovskite nanocrystals, thereby causing the emission light wavelength to red-shift or blue-shift, achieving adjustable emission spectra.

### Experimental Example 2

First, 0.31 g of cesium acetate and 28.8 mL of mixed solvent of n-propanol and n-hexane were weighed and added to a glass bottle. The mixture was stirred at room temperature under atmospheric conditions to complete the preparation of the cesium precursor solution. Moreover, the volume ratio of n-propanol to n-hexane in Experimental Example 2 was fixed at 1:2.

Then, 0.5872 g to 3.5233 g of lead bromide and 4.32 mL of n-propanol were weighed and added to a single-neck flask. The single-neck flask was heated and stirred, with the detailed amount of lead bromide and the mole ratio of cesium acetate to lead bromide listed in the following Table 2. Subsequently, 4.32 mL of octanoic acid and 4.32 mL of octylamine were added sequentially. The temperature of the single-neck flask was raised to 100° C., and after the solution became clear, the preparation of the lead precursor solution was completed.

The subsequent method for mixing the cesium precursor solution and the lead precursor solution until the preparation of the colloidal halide perovskite nanocrystal solution was completed was the same as in Experimental Example 1.

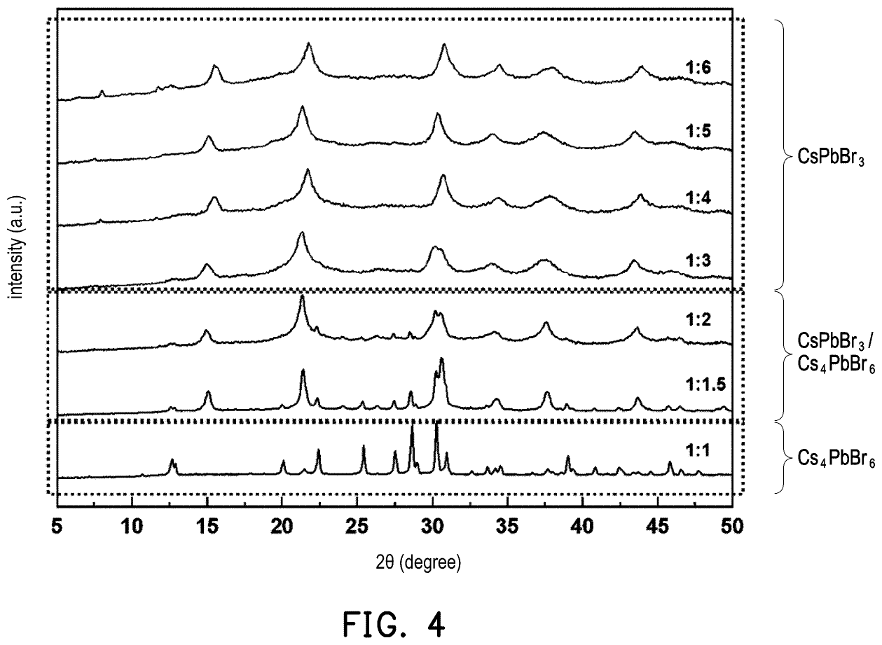

Then, samples were prepared according to the method in Experimental Example 1, followed by X-ray diffraction analysis (XRD analysis), resulting in FIG. 4.

From FIG. 4, it may be obtained that changing the mole ratio of the cesium precursor to the lead precursor (marked on the right side of the XRD curves) can control the composition of the formed halide perovskite nanocrystals. When the mole ratio of cesium acetate to lead bromide is 1:1, the obtained product is Cs₄PbBr₆ nanocrystals; when the mole ratio of cesium acetate to lead bromide is 1:1.5 and 1:2, the obtained product is CsPbBr₃/Cs₄PbBr₆ mixed structure nanocrystals; when the mole ratio of cesium acetate to lead bromide is 1:3, 1:4, 1:5, and 1:6, the obtained product is CsPbBr₃.

Then, the emission spectra (PL) of the colloidal halide perovskite nanocrystals formed with different precursor mole ratios were measured, and the PL wavelength and PLQY were obtained from the PL spectra, with the results shown in the following Table 2. Additionally, the X-ray voltage was fixed at 80 kV, the measurement distance was fixed at 15 cm, and a fiber optic probe was used to collect radioluminescence data to obtain the RL intensity, with the results also shown in the following Table 2.

TABLE 2

| | mole ratio of cesium acetate to lead bromide | | | | | | |
|---|---|---|---|---|---|---|---|
| | 1:1 | 1:1.5 | 1:2 | 1:3 | 1:4 | 1:5 | 1:6 |
| lead bromide content (g) | 0.5872 | 0.8808 | 1.1744 | 1.7616 | 2.3489 | 2.9361 | 3.5233 |
| PL wavelength (nm) | 537.8 | 538.3 | 534.8 | 525.5 | 516.7 | 515.6 | 516.1 |
| PLQY (%) | 23.64 | 34.68 | 35.13 | 32.29 | 29.07 | 30.01 | 24.07 |
| RL intensity | 6125 | 10408 | 8901 | 6562 | 8740 | 7650 | 8963 |

From Table 2, it may be obtained that changing the mole ratio of Cs to Pb, for example, gradually increasing the proportion of Pb, causes a blue-shift trend in the emission wavelength. Moreover, when the mole ratio of cesium acetate to lead bromide is 1:1.5 and 1:2, forming colloidal halide perovskite nanocrystals with a CsPbBr₃/Cs₄PbBr₆ mixed structure (i.e.), a dual-peak emission trend can be observed in the PL spectrum, and a higher PLQY % can be estimated, indicating that energy transfer exists between the two structures, thereby reducing self-absorption phenomena and enhancing fluorescence emission. As with the PLQY % results, the CsPbBr₃/Cs₄PbBr₆ mixed structure is conducive to enhancing fluorescence emission intensity and may have a higher radioluminescence intensity under X-ray irradiation.

### Experimental Example 3

The preparation method was the same as in Experimental Example 1, but 0.1666 g of formamidine acetate (FAAc) was used instead of cesium acetate, and a mixed solvent with a volume ratio of 1:2 of n-propanol to n-hexane was added to the glass bottle. The mixture was stirred under atmospheric conditions at room temperature to complete the preparation of the formamidine precursor solution.

The subsequent steps and components were the same as in Experimental Example 1 to obtain a colloidal FAPbBr₃ nanocrystal solution.

### Experimental Example 4

The preparation method was the same as in Experimental Example 3, but 0.1458 g of methylammonium acetate (MAAc) was used instead of FAAc. The subsequent steps and components were the same as in Experimental Example 3 to obtain a colloidal MAPbBr₃ nanocrystal solution.

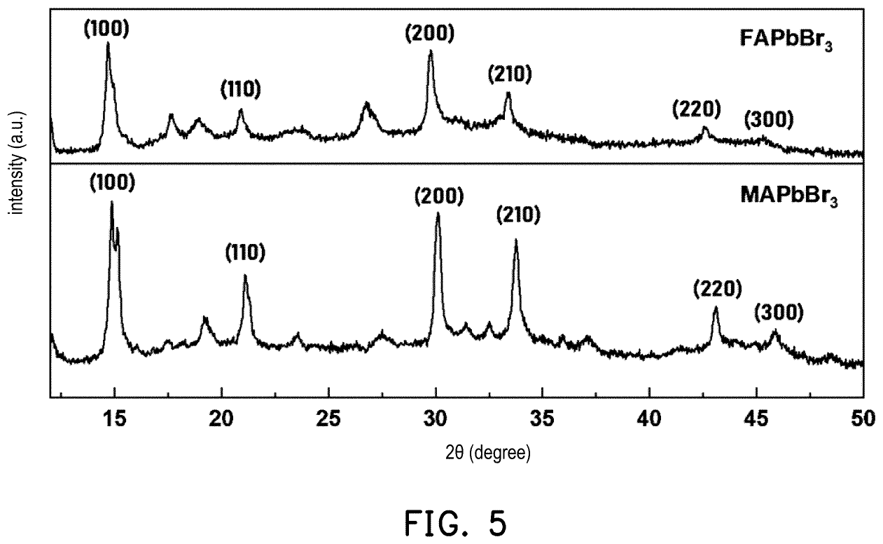

Then, samples for Experimental Example 3 and Experimental Example 4 were prepared according to the method of Experimental Example 1, followed by XRD analysis to obtain FIG. 5.

From FIG. 5, it may be observed that the diffraction peaks in the XRD patterns correspond to the structures of FAPbBr₃ and MAPbBr₃, respectively. This confirms that the same preparation method can indeed form other colloidal halide perovskite nanocrystals disclosed in this disclosure.

### Experimental Example 5

Selection of colloidal halide perovskite nanocrystals:

Small crystal size: The colloidal CsPbBr₃ nanocrystals formed in Experimental Example 1 with a volume ratio of n-propanol to n-hexane of 1:5 have a crystal size of approximately 1.5 nm.

Medium crystal size: The colloidal CsPbBr₃ nanocrystals formed in Experimental Example 1 with a volume ratio of n-propanol to n-hexane of 1:2 have a crystal size of approximately 3.1 nm.

Large crystal size: The colloidal CsPbBr₃ nanocrystals formed in Experimental Example 1 with a volume ratio of n-propanol to n-hexane of 3:1 have a crystal size of approximately 10.9 nm.

Concentration of colloidal solution: 60 mg/mL (solvent: toluene).

Process temperature: room temperature (RT).

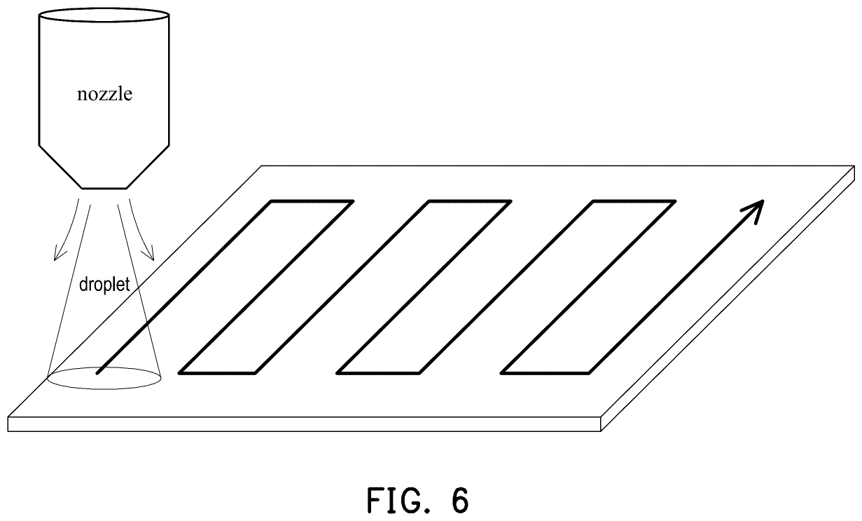

Ultrasonic spray coating process: The colloidal halide perovskite nanocrystals are atomized into droplets using an ultrasonic frequency of 20 Hz to 100 Hz, and the droplets are deposited with the assistance of dry air, as shown in FIG. 6.

FIG. 6 shows the droplets being sprayed from the nozzle, and the continuous spray coating is conducted on a substrate with a nozzle speed of 25 mm/s and an output rate of 0.8 mL/min. The thickness of each layer is controlled by the number of spray coating cycles, where one cycle is defined as the completion of coating the entire substrate surface and returning to the starting point of the spray coating.

In Experimental Example 5, bilayer and trilayer structures (each layer sprayed for 5 cycles) with different arrangement methods are studied to investigate the trends in emission wavelength and intensity. The combinations of various crystal sizes are listed in the following Table 3.

After completing the fabrication of each sensing film, the RL spectrum was measured, and the RL wavelength was obtained from the RL spectrum. Then, with the X-ray voltage fixed at 80 kV and the measurement distance fixed at 15 cm, the radioluminescence data was collected using a fiber optic probe to obtain the RL intensity. The results of RL wavelength and RL intensity are all shown in the following Table 3.

### Comparative Example

The sensing films are fabricated in the same method as in Experimental Example 5, but using the same crystal size composition to form bilayer and trilayer structures.

Then, the RL spectra of the sensing films from Experimental Example 5 and the Comparative Example were measured, and the RL intensity was obtained from the RL spectra. The results are shown in the following Table 3.

TABLE 3
bilayer

| | bottom layer/top layer | | | | |
|---|---|---|---|---|---|
| | S/S | S/M | S/L | M/S | M/M |
| RL intensity | 1181.375 | 2311.9 | 2245.45 | 1946.075 | 2028.55 |
| (counts.) | | | | | |

bilayer

bottom layer/top layer

| | M/L | L/S | L/M | L/L |
|---|---|---|---|---|
| RL intensity | 2663.275 | 2181.425 | 2636.7 | 2484.75 |
| (counts.) | | | | |

trilayer

| | bottom layer/middle layer/top layer | | | | |
|---|---|---|---|---|---|
| | S/S/S | S/M/L | S/L/M | M/S/L | M/M/M |
| RL intensity | 3907.75 | 3724.225 | 3526.05 | 3959.975 | 3282.975 |
| (counts.) | | | | | |

trilayer

bottom layer/middle layer/top layer

| | M/L/S | L/S/M | L/M/S | L/L/L |
|---|---|---|---|---|
| RL intensity | 3972.7 | 3386.75 | 3927.55 | 3143.375 |
| (counts.) | | | | |

In the table, S represents colloidal halide perovskite nanocrystals with small crystal size, M represents colloidal halide perovskite nanocrystals with medium crystal size, and L represents colloidal halide perovskite nanocrystals with large crystal size.

From Table 3, it may be obtained that when the bilayer structure is composed of larger crystals (M and L), it has a higher radioluminescence intensity. For example, the bottom layer/top layer structures of M/L or L/M both have RL intensities above 2500. Moreover, bilayer structures composed of different crystal sizes generally have better radioluminescence intensities. As for the trilayer structures, those composed of different crystal sizes generally have better radioluminescence intensities. For instance, the structures with bottom layer/middle layer/top layer of M/S/L, M/L/S, and L/M/S have even higher radioluminescence intensities.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A sensing film of an X-ray image sensor, comprising a multilayer colloidal halide perovskite nanocrystal, wherein:
the colloidal halide perovskite nanocrystal in different layers have different crystal sizes.

2. The sensing film of the X-ray image sensor according to claim 1, wherein a chemical formula of the colloidal halide perovskite nanocrystals is ABX₃, and an organic ligand is introduced, wherein A comprises monovalent metal cations or monovalent organic amine cations, B comprises divalent metal cations, X comprises halogen anions, and the organic ligand comprises carboxyl groups (RCOOH), alkylamines (RNH₂) or combinations thereof.

3. The sensing film of the X-ray image sensor according to claim 2, wherein the A is selected from at least one of Cs⁺, Rb⁺, CH₃NH₃⁺ and CH(NH₂)₂⁺; the B is selected from at least one of Pb²⁺ and Sn²⁺; the X is selected from at least one of Cl⁻, Br⁻ and I⁻.

4. The sensing film of the X-ray image sensor according to claim 2, wherein the organic ligand is selected from at least one of combinations of octanoic acid and octylamine, or oleic acid and oleylamine.

5. The sensing film of the X-ray image sensor according to claim 1, wherein the crystal size of the multilayer colloidal halide perovskite nanocrystal is between 1 nm and 100 nm.

6. The sensing film of the X-ray image sensor according to claim 1, wherein the multilayer colloidal halide perovskite nanocrystal has a trilayer structure, and the crystal size is stacked from large to small from bottom to top.

7. The sensing film of the X-ray image sensor according to claim 1, wherein the multilayer colloidal halide perovskite nanocrystal has a trilayer structure, and the crystal sizes of a bottom layer, a middle layer, and a top layer of the trilayer structure are composed of a medium size, a small size, and a large size, respectively.

8. The sensing film of the X-ray image sensor according to claim 1, wherein the multilayer colloidal halide perovskite nanocrystal has a trilayer structure, and the crystal sizes of a bottom layer, a middle layer, and a top layer of the trilayer structure are composed of a medium size, a large size, and a small size, respectively.

9. The sensing film of the X-ray image sensor according to claim 1, wherein the multilayer colloidal halide perovskite nanocrystal has a bilayer structure, and the crystal size is stacked from large to small, the crystal size of a bottom layer of the bilayer structure is between 9 nm and 20 nm, and the crystal size of a top layer of the bilayer structure is between 3 nm and 9 nm.

10. The sensing film of the X-ray image sensor according to claim 1, wherein the multilayer colloidal halide perovskite nanocrystal has a bilayer structure, and the crystal size is stacked from small to large, the crystal size of a bottom layer of the bilayer structure is between 3 nm and 9 nm, and the crystal size of a top layer of the bilayer structure is between 9 nm and 20 nm.

11. An X-ray image sensor, comprising the sensing film according to claim 1.

12. A method for manufacturing a sensing film of an X-ray image sensor, comprising:
formulating a plurality of colloidal solutions, wherein each of the colloidal solutions comprises halide perovskite nanocrystals with different crystal sizes; and
spraying the colloidal solutions to form a multilayer colloidal halide perovskite nanocrystal.

13. The method for manufacturing the sensing film of the X-ray image sensor according to claim 12, wherein a concentration of the colloidal solutions is from 10 mg/mL to 150 mg/mL.

14. The method for manufacturing the sensing film of the X-ray image sensor according to claim 12, wherein a chemical formula of the colloidal halide perovskite nanocrystals is ABX₃, and an organic ligand is introduced, wherein A comprises monovalent metal cations or monovalent organic amine cations, B comprises divalent metal cations, X comprises halogen anions, and the organic ligand comprises carboxyl groups (RCOOH), alkylamines (RNH₂) or combinations thereof.

15. The method for manufacturing the sensing film of the X-ray image sensor according to claim 14, wherein the A is selected from at least one of Cs⁺, Rb⁺, CH₃NH₃⁺ and CH(NH₂)₂⁺; the B is selected from at least one of Pb²⁺ and Sn²⁺; the X is selected from at least one of Cl⁻, Br⁻ and I⁻.

16. The method for manufacturing the sensing film of the X-ray image sensor according to claim 14, wherein the organic ligand is selected from at least one of combinations of octanoic acid and octylamine, or oleic acid and oleylamine.

17. The method for manufacturing the sensing film of the X-ray image sensor according to claim 12, wherein formulating the colloidal solutions comprises:
preparing a first precursor solution, the first precursor solution comprising a first precursor, an alcoholic polar solvent, and a non-polar solvent;
preparing a second precursor solution, the second precursor solution comprising a second precursor and an organic ligand;
mixing the first precursor solution with the second precursor solution to obtain a product;
purifying the product; and
dispersing the product in a solvent to obtain the colloidal solutions.

18. The method for manufacturing the sensing film of the X-ray image sensor according to claim 17, wherein the first precursor is a cesium precursor, the second precursor is a lead precursor, the alcoholic polar solvent comprises n-propanol, isopropanol, n-butanol, tert-butanol or n-hexanol, and the non-polar solvent comprises n-hexane, toluene, octane or heptane.

19. The method for manufacturing the sensing film of the X-ray image sensor according to claim 18, wherein a volume ratio of n-propanol to n-hexane is from 5:1 to 1:8.

20. The method for manufacturing the sensing film of the X-ray image sensor according to claim 18, wherein a mole ratio of the cesium precursor to the lead precursor is from 1:1 to 1:6.

21. The method for manufacturing the sensing film of the X-ray image sensor according to claim 12, wherein spraying the colloidal solutions comprises inkjet printing or ultrasound spray coating process.

22. The method for manufacturing the sensing film of the X-ray image sensor according to claim 21, wherein the ultrasound spray coating process comprises atomizing one of the colloidal solutions at an ultrasound frequency of 20 Hz to 100 Hz to form droplets, and assisting a deposition of the droplets with dry air, argon gas, or nitrogen gas.
